(19) United States
(12) Patent Application Publication
(10) Pub. No.: US 2026/0231365 A1
(43) Pub. Date: Aug. 6, 2026

(54) ENCAPSULANT RETAINING WRAP FOR MICRO-AXIAL PUMP

(71) Applicant: HEWLETT PACKARD ENTERPRISE DEVELOPMENT LP, Spring, TX (US)

(72) Inventors: Kasey Renee Lench, Porter, TX (US); John P. Franz, Tomball, TX (US)

(21) Appl. No.: 19/192,790

(22) Filed: Apr. 29, 2025

Related U.S. Application Data
(60) Provisional application No. 63/752,009, filed on Jan. 31, 2025.

(51) Int. Cl. H05K 7/20; F04D 3/02; F04D 13/06; F04D 29/58

(52) U.S. Cl. CPC H05K 7/20272; F04D 3/02; F04D 29/5893; F04D 13/06

(57) ABSTRACT

An axial pump for delivering liquid coolant to cool an electronic device comprises a conduit defining a liquid flow path and an impeller/rotor disposed in the conduit. A stator outside the conduit drives rotation of the impeller/rotor about an axis of rotation parallel to the liquid flow path. A printed circuit assembly (PCA) supplies driving signals to the stator. A housing is formed from multiple distinct housing portions having seams therebetween. A thermal encapsulant is injected, in liquid form, into the housing, with the encapsulant later curing to solid form to thermally couple the stator and the PCA to the conduit, thereby enabling cooling of the stator and PCA via the liquid flowing though the conduit. An encapsulant retaining wrap is adhered to the housing prior to the injection of the encapsulant, with the wrap retaining the encapsulant within the housing by covering at least some of the seams.

### PRIORITY CLAIM

This application claims priority to U.S. Provisional Patent Application No. 63/752,009, filed Jan. 31, 2025, the contents of which are incorporated herein.

### INTRODUCTION

Some information processing systems utilize liquid cooling techniques to remove heat from the system. In these systems, a liquid coolant is circulated in a loop through the information processing devices (e.g., servers, networking devices, etc.) of the system, and heat generating components thereof (e.g., processors) are thermally coupled (e.g., via cold plates) to the liquid coolant so that the liquid coolant absorbs heat from these components. As the now-heated coolant exits the information processing devices, it carries the heat to a cooling device (such as a heat exchanger) which cools the liquid back to a desired operating temperature, whereupon the cooled liquid is circulated through the loop once again, extracting more heat from the information processing devices. Such a liquid cooling loop uses one or more pumps to drive the circulation of the liquid through the loop. Often, these pumps are disposed in a so-called coolant distribution unit (CDU) that provides a centralized pumping unit to circulates the liquid collectively through multiple information processing devices (e.g., an entire rack, or multiple racks, of such devices). These pumps are usually very large, with the CDU often taking up a substantial portion of a rack, or in some cases a full rack.

### BRIEF DESCRIPTION OF THE DRAWINGS

The present disclosure can be understood from the following detailed description, either alone or together with the accompanying drawings. The drawings are included to provide a further understanding of the present disclosure and are incorporated in and constitute a part of this specification. The drawings illustrate one or more examples of the present teachings and together with the description explain certain principles and operations. In the drawings:

FIG. 1 is a schematic diagram illustrating an example pump.

FIGS. 2-10D illustrate another example pump. In FIGS. 2-5, an encapsulant retaining wrap of the pump is omitted from the views to simplify the drawings and avoid obscuring other details. In FIGS. 6-8, an example encapsulant retaining wrap is shown, both in isolation and in connection with other parts of the pump, with FIG. 8 showing the fully assembled pump with the wrap installed. FIGS. 9-10D illustrate a variation of the encapsulant retaining wrap, both in isolation and in connection with the other parts of the pump.

FIG. 2 is a perspective view of the pump of FIGS. 2-10D with the encapsulant retaining wrap omitted from the view.

FIG. 3 is an exploded view of the pump of FIG. 2.

FIG. 4 is an exploded perspective view of an impeller chamber subassembly of the pump of FIG. 2, including a perspective sectional view of a portion of the impeller chamber subassembly with the section taken along the plane 4-4 indicated in FIG. 2.

FIG. 5 is a cross-section of the pump of FIG. 2, with the section taken along the plane 4-4 indicated in FIG. 2.

FIG. 6 is plan view of a base portion of an encapsulant retaining wrap for the pump of FIG. 2, with the base in an unfolded state.

FIG. 7 is an exploded view of the pump of FIG. 2 showing the encapsulant retaining wrap of FIG. 6 in a folded state and exploded relative to the housing of the pump.

FIG. 8 is a perspective view of the pump of FIG. 2 with the encapsulant retaining wrap of FIG. 7 installed thereon.

FIG. 9 is an exploded view of the pump of FIG. 2 showing another wrap, which is a variation on the encapsulant retaining wrap of FIG. 6, in a folded state and exploded relative to the housing of the pump.

FIG. 10A shows a housing-facing side of a base assembly of the wrap of FIG. 9. FIG. 10B shows an exterior-facing side of the base assembly of the wrap. FIG. 10C shows a housing-facing side of a cover assembly of the wrap of FIG. 9. FIG. 10D shows an exterior-facing side of the cover assembly of the wrap.

FIG. 11 is a schematic diagram of an information processing system with a pump.

### DETAILED DESCRIPTION

In some cases, it may be desired to utilize relatively small pumps in liquid cooling loops, rather than the commonly used large CDU pumps. One advantage of using smaller pumps for liquid cooling information processing systems is that the smaller pumps can be more efficient than the larger pumps, in terms of the amount of liquid they can move per unit of energy spent. The smaller pumps can also fit in places that the large pumps will not, which opens opportunities for system designers to arrange their systems in new and potentially more efficient ways which would not have otherwise been possible. For example, smaller pumps can allow for a distributed pumping architecture to be utilized, in which each information processing device is provided with one or more small pumps localized to the device (e.g., disposed within, or adjacent to, the chassis of the device) to control the circulation of fluid locally through that device in an individualized manner, rather than using a single large centralized pumping unit to control the flow of fluid collectively through all the devices in a rack or multiple racks. This distributed approach can improve efficiency and performance of the liquid cooling loop, potentially reducing power usage and noise while also delivering more coolant flow (and hence better cooling). In addition, this may also facilitate greater modularity and scalability of the system, as the pumping capacity of the system naturally scales along with the demand for cooling, since each new device added to the system brings its own pump(s) with it.

While having smaller pumps can in theory be advantageous, realizing these advantages can be challenging with existing pump technologies. Many existing pumps that can produce the needed levels of pressure and liquid flow rates for liquid cooling an information processing device are simply too large, or are too awkwardly shaped, to fit well within the densely packed environment of an information processing device. Other pumps (such as artificial heart pumps) may be small enough to fit in a space-constrained information processing system, but these generally have inadequate pumping characteristics (e.g., insufficient pressure, insufficient flow rates, poor efficiency, etc.) for the liquid cooling context. In other words, it is challenging to find pumps which both have a suitable small form factor and which have desired pumping characteristics.

Thus, to meet this unique combination of challenges, specialized pumps are being developed, such as the micro-axial pumps described in U.S. Pat. No. 11,015,608 B2, the contents of which are incorporated herein by reference in their entirety. An axial pump has an impeller (the part that moves within the liquid to drive the flow) that spins along an axis that is coaxial with a flow direction of the liquid, in contrast to centrifugal pumps which have impellers that spin along an axis transverse to the flow direction of the liquid. In addition, in certain micro-axial pumps such as those disclosed in U.S. Pat. No. 11,015,608 B2, the rotor (the part which is magnetically driven to rotate) is attached directly to the impeller forming a rotor/impeller assembly which is entirely disposed within the fluid channel, as opposed to having a rotor sitting outside of the fluid channel with a shaft piercing through a wall of the channel and connecting the rotor to the impeller. A stator sitting outside the fluid channel generates magnetic fields in response to receiving electrical driving current, these magnetic fields interact with permanent magnets in the rotor to generate a torque on the impeller/rotor assembly which causes it to spin, and blades extending along the exterior of the spinning impeller push liquid through the pump. The axial arrangement, together with various other improvements, allows for the micro-axial pumps to have a form factor which is both extremely small and conveniently shaped (e.g., rectangular in cross-section), while still providing the same or better effectiveness and efficiency as larger pumps. For example, some micro-axial pumps under development may be similar in size and shape to a deck of cards while being capable of providing flow rates of such as 4 GPM at 4PSID, 2 GPM at 11.5 PSID, or 1 GPM at 13.9 PSID (PSID refers to a pressure drop in pounds per square inch).

However, the size and form factor of such micro-axial pumps can pose a variety of technical challenges. For example, it can be difficult, in some cases, to adequately cool the pump. In particular, in a system in which all cooling is provided by liquid coolant and no air circulation is present, the pump may overheat, which can cause premature wear. In some cases, the liquid coolant that flows through the pump does not adequately cool the pump because it some of the main heat generating parts of the pump—namely the stator and the control PCA—are exterior to the liquid conduit and thus are not strongly thermally coupled with the liquid coolant flowing through the liquid conduit.

To address these and other challenges, example pumps disclosed herein have a thermal encapsulant injected into the interior of their housing after assembly, with the thermal encapsulant thermally coupling the heat generating components which are outside of the liquid conduit, such as the stator and control PCA, with the liquid conduit. The thermal encapsulant is initially liquid and thus can flow into and fill in the gaps between the various parts of the pump. The thermal encapsulant then cures into solid form. Because the encapsulant is in mutual contact with, and fills the gaps between, the heat generating parts and the liquid conduit, a heat transfer path is established therebetween via the encapsulant. Thus, heat can flow from the heat generating parts into liquid coolant flowing through the conduit, thereby cooling the pump.

When injecting the thermal encapsulant, it is possible for some of the liquid encapsulant to leak out of the housing. This leakage may occur because the housing is not formed from a unitary (monolithic) body without gaps or openings. Instead, the housing is formed from multiple distinct housing portions which are arranged together to form a housing. For example, the pump may have multiple distinct subassemblies, such as a liquid conduit subassembly, stator subassemblies, and inlet and outlet subassemblies, and these subassemblies may be formed separately and then later assembled together to form the pump, and each of these subassemblies may include a portion of the housing. Accordingly, where these different housing portions meet, there will be a gap or seam through which the liquid encapsulant can leak. This leakage can leave air pockets within the housing in places where encapsulant should have been present, which can diminishing the capability of the encapsulant to thermally couple the heat generating components to the liquid conduit. Thus, the pump may not receive the level of cooling that it needs. In addition, when the leaked encapsulant cures, it can leave an unsightly residue on the exterior of the pump.

To address these additional challenges, example pumps disclosed herein may further include an encapsulant retaining wrap. The encapsulant retaining wrap may comprise a thin sheet of material that is folded to a shape that fits around the bottom portion of the housing of the pump. The wrap is adhered to the bottom portion of the pump, covering the seams between the housing portions on the bottom side of the housing. The wrap holds the liquid encapsulant within the housing, reducing leakage. In addition, the wrap may also serve as a cosmetic sticker and/or product label for the pump, carrying product information and branding/trade dress. Using the same material to both retain the encapsulant during manufacture and to serve as the product label can reduce material costs and manufacturing steps.

Turning now to the figures, various devices, systems, and methods in accordance with nonlimiting aspects of the present disclosure will be described.

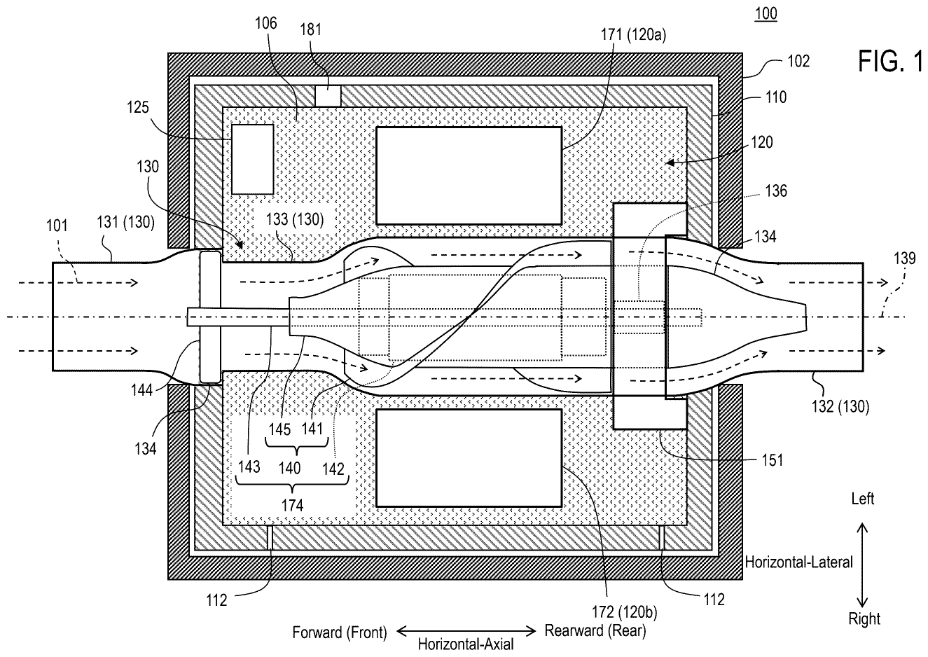

FIG. 1 is a schematic diagram conceptually illustrating a pump 100. FIG. 1 shows the pump 100 from a perspective above the pump and illustrates functional and some general positional relationships between components, as described below, but the diagram is schematic in nature and is not intended to illustrate specific shapes, dimensions, or other structural details accurately or to scale. It should be understood that implementations of the pump 100 can vary from one another in various aspects. Some implementations of the pump 100 may have different numbers and arrangements of the illustrated components. Some implementations of the pump 100 may include other parts that are not illustrated in FIG. 1. Some implementations of the pump 100 may omit one or more of the parts that are illustrated in FIG. 1.

As shown in FIG. 1, the pump 100 comprises a housing 110, a stator 120 (also “motor stator 120”), control circuitry 125, a conduit 130 defining a liquid flow path 101, and an impeller/rotor sub-assembly 174 comprising an impeller 140, a rotor 142, and a shaft 143. The housing 110 and conduit 130 are shown as transparent to allow visibility of the other components. In addition, some parts (or portions of parts) which are covered by (e.g., contained within) other parts are shown in dotted lines; this is done to make it easier to visually distinguish the covered parts from the covering parts. The components of the pump 100 will be described in greater detail below.

The housing 110 comprises one or more walls or other support structures that support and at least partially enclose or house some of the other components of the pump 100. The housing 110 may be a single part or made from multiple parts assembled together. In some examples, the parts of the housing 110 may also be coupled to and/or form an integral part of the other parts of the pump 100. For example, portions of the conduit 130 may also form parts of the housing 110.

The conduit 130 comprises walls that partially enclose a volume and define the liquid flow path 101 through that volume, with the liquid flow path 101 being the path along which liquid coolant (e.g., water or other coolants) flows as it traverses the pump 100. The conduit 130 comprises a pump inlet portion 131 (also “inlet 131”) having a first opening into the enclosed volume of the conduit 130, a pump outlet portion 132 (also “outlet 132”) having a second opening into the enclosed volume of the conduit 130, and an impeller chamber portion 133 between the other two portions 131/132. The impeller chamber portion 133 houses the impeller 140 and is fluidically coupled to the inlet 131 and outlet 132. The pump inlet portion 131 and pump outlet portion 132 may comprise structures for fluidically coupling the pump with coolant lines of a liquid cooling loop, such as hose barbs, fittings, quick connect couplings, and/or other liquid coupling mechanisms as would be familiar to those of ordinary skill in the art. The conduit 130 may be liquid tight, sealing the interior volume from an exterior environment, other than at openings in the inlet 131 and outlet 132 that allow the enclosed interior volume to be fluidically coupled to the exterior environment (e.g., to coolant lines of a liquid cooling loop). In some examples, the inlet 131 and outlet 132 may extend outside of the housing 110 of the pump 100. In some examples, the impeller chamber portion 133 is contained within the housing 110.

The conduit 130 has a central longitudinal axis. This axis is coaxial with various other axes of other parts of the pump 100, including a rotational axis of the rotor 142, a rotational axis of the impeller 140 (described below), and a central longitudinal axis of a shaft 143, and therefore all of these axes are depicted in FIG. 1 by the same axis 139. Accordingly, all of these co-axial axes may hereinafter be referred to interchangeably as the axis 139. Liquid flowing through the conduit 130 flows, as whole, along directions parallel to the axis 139, as indicated by the dashed arrows representing the flow path 101 in FIG. 1. Note that the liquid may also spiral circumferentially around the axis 139 (in addition to moving axially) while traversing certain portions of the flow path 101 (e.g., while passing the impeller 140), but the bulk or average motion of the liquid as a whole in traversing the conduit 130 is along directions parallel to the axis 139. The liquid flow path 101 is shown in FIG. 1 to illustrate how the pump 100 is configured to flow liquid when deployed, but note that the liquid is not necessarily part of the pump 100 and is not necessarily present in all states of the pump 100. For example, prior to being deployed in a liquid cooling loop, there might be no liquid in the pump 100.

As mentioned above, the impeller/rotor sub-assembly 174 comprises an impeller 140 and a rotor 142 attached together and disposed within the conduit 130. The impeller/rotor sub-assembly 174 also comprises a shaft 143 to which rotor 142 is rotatably attached such that the rotor 142, and the impeller 140 coupled thereto, can rotate about the shaft 143. A rotation axis of the rotor 142, a rotation axis of the impeller 140, a longitudinal axis of the shaft 143, and a longitudinal axis of the conduit 130, are all coaxial, as mentioned above. The shaft 143 is fixedly attached to the housing 110, and thus when the rotor 142 and impeller 140 rotate about the shaft 143, they are also rotating relative to the housing 110. The impeller 140 and the rotor 142 will be described in greater detail in turn below.

The impeller 140 is housed within the conduit 130, specifically in the impeller chamber 133 thereof. The impeller 140 is configured to, when rotated about the axis 139, drive liquid to flow along the flow path 101 through the conduit 130. The impeller 140 comprises an impeller body 145 and blades 141 that protrude radially from and spiral along/around the impeller body 145. References to the blades 141 spiraling along or around the impeller body 145 mean that the blades 145 extend along paths that axially traverse the impeller body 145 while simultaneously circling circumferentially around the impeller body 145 through at least portions of the path; for example, the paths could be helical. The blades 141 are configured to force the liquid axially along the flow path 101 through the conduit 130 as the impeller 140 rotates.

The impeller body 145 is hollow (i.e., has an internal bore therethrough) and the rotor 142 is at least partially contained within the hollow interior of the impeller 140. Specifically, the impeller body 145 may have a shape roughly of a hollow cylinder with openings at both ends and with one end being tapered/rounded. The shaft 143 also extends through the internal bore of the impeller body 145.

In some examples, the impeller body 145 and the impeller blades 141 are integrally connected, meaning they are formed together as two parts of the same monolithic body. The impeller body 145 may be formed from any solid material which can be formed into the desired shape. For example, the impeller body 145 may be formed from various plastics, which can be formed into the desired shape by injection molding, additive manufacturing (e.g., 3D printing), or other techniques. As another example, the impeller body 145 may be formed from various metals, which can be formed into the desired shape by casting, additive manufacturing (e.g., 3D printing), or other techniques.

The rotor 142 comprises magnetic portions (e.g., permanent magnets) and bearings, which are coupled together such that the bearings support the magnetic portions. The bearings are in turn rotatably coupled to the shaft 143 such that the rotor 142 can rotate about the shaft 143. Specifically, the magnetic portions of the rotor 142 are arranged to interact with magnetic fields generated by the stator 120 (which will be described below) to produce rotation of the rotor 142. The rotor 142 is disposed within and attached to the impeller body 145 (e.g., by press-fitting, adhesive, or other means), such that the rotation of the rotor 142 causing the impeller 140 attached thereto to also rotate. Thus, the rotor 142 and the stator 120 may together form an electromagnetic motor. The magnetic portions may comprise permanent magnets and/or magnetically attractable (e.g., ferromagnetic) materials (e.g., iron, steel, etc.) which are capable of interacting with (e.g., being attracted or repelled by) the generated magnetic fields. In some examples, the magnetic portions comprise multiple permanent magnets which are distributed circumferentially around the axis 139 and arranged with alternating polarities.

As shown in FIG. 1, the shaft 143 is secured to the conduit 130 and housing 110 via a front support 144 and a rear support 151. The front support 144 engages and holds a front portion of the shaft 143 and is coupled to the walls of the conduit 130. The rear support 151 engages and holds a rear portion of the shaft 143 and is also coupled to the walls of the conduit 130. Front and rear are used herein in relation to the orientation of the pump 100 illustrated in FIG. 1, with the inlet side being the “front” side and the outlet side being the “rear” side. However, these terms are meant merely to aid understanding and are not limiting. In particular, in some examples of the pump 100, the supports 144 and 151 could be reversed in orientation, with the support 144 being nearer the outlet 132 and the support 151 being nearer the inlet 131, in which case the terms “front” and “rear” as used herein would be reversed in relation to these components.

In some examples, the pump 100 further comprises an adjustment mechanism 136. The adjustment mechanism 136 couples the shaft 143 to the rear support 151. The adjustment mechanism 136 is actuatable, and when actuated changes the position of the shaft 143 relative to the rear support 151, and hence also relative to the impeller chamber 133. More specifically, the adjustment mechanism 136 is configured to cause translation along the rotation axis 139 of the rear end of the shaft 143 relative to the rear support 151, which in turn causes translation of the front end of the shaft 143 relative to the front support 144. Because the shaft 143 is coupled to the rotor 132 and the rotor 132 is coupled to the impeller 140, when the shaft 143 is translated along the axis 139 this also causes the impeller 140 to be translated along the axis 139 relative to conduit 130. Adjusting the position of the impeller 140 in this manner can change the clearance between the blades 141 and the walls of the conduit 130, particularly near the front end of the impeller 140. This can allow for smaller clearances to be obtained between the blades 141 and conduit 130, which improves performance, without requiring high precision in the parts which would inordinately increase costs. The adjustment mechanism 136 may include, in some examples, any of the adjustment mechanisms described in U.S. patent application Ser. No. 17/977,200 entitled “AXIAL PUMP WITH ADJUSTABLE IMPELLER” and filed on Oct. 31 2022, the entire contents of which is incorporated herein by reference.

The control circuitry 125 is configured to control operations of the pump 100. In some examples the control circuitry 125 comprises a printed circuit assembly (PCA) with various electronic components formed therein and/or mounted thereon, and/or additional components external to the PCA. In some examples the control circuitry 125 includes logic to drive operations of the pump 100. For example, control circuitry 125 may include a microcontroller. As another example, the control circuitry 125 may include discrete logic circuits (digital or analog), in addition to or instead of a microcontroller. The control circuitry 125 may also include sensors, such as temperature sensors, electrical power usage sensors, moisture sensors (e.g., for leak detection), magnetic field (e.g., Hall effect) sensors, or other sensors. The control circuitry 125 may also include power delivery components, such as transistors or other switches (e.g., relays), capacitors, diodes, etc. In some examples, the control circuitry 125 may include communications components for communicating with outside devices such as a system controller, baseboard management controller (BMC), rack controller, etc., for example via the cables (not illustrated) coupled to the pump 100 and/or wirelessly (via, e.g., Bluetooth, WiFi, etc.). The control circuitry 125 may be electrically coupled to the stator 120 to provide electrical signals thereto to drive the operation of the stator 120. The control circuitry 125 may be coupled to an outside power source and/or an outside controller via wires or cables (not illustrated).

The stator 120 is configured to receive electrical power from the control circuitry 125 and in response generate alternating magnetic fields that interact with the rotor 142 of the impeller/rotor sub-assembly 174 to cause the rotor 142 (and hence the impeller 140 coupled thereto) to rotate about a rotation axis thereof, depicted in FIG. 1 as axis 139. As shown in FIG. 1, the stator 120 comprises a first stator portion 120a and a second stator portion 120b arranged on diametrically opposite lateral sides of the conduit 130. Each of these stator portions 120a/120b comprises a stator core and wire windings wound around the stator core. The windings generate magnetic fields in response to electric current flowing therethrough. The stator cores include stator teeth which extend and shape the generated magnetic fields in the desired pattern around the conduit 130, such that the magnetic fields can drive rotation of the rotor 142. The stator cores are made from magnetically susceptible materials, which in some examples may be arranged in a laminated stack. The stator portion 120a is coupled to a support frame, and together this forms a first stator subassembly 171. Similarly, stator portion 120b is coupled to another support frame, and together this forms a second stator subassembly 171. The PCA 125 may also be part of the subassemblies 171 and/or 172, with portions thereof being held by the support frames.

In some examples, the two stator cores together form a combined stator core having a cross-sectional profile which is rectangular in shape. As used herein, a rectangular cross-sectional profile means that, in a cross-section perpendicular to the central axis of the pump, a rectangle can be drawn around the combined stator core in which: (a) the top edges of both of the stator cores correspond to (e.g., align with and follow/trace) a top edge of the rectangle, (b) the bottom edges of both of the stator cores correspond to a bottom edge of the rectangle, (c) the outer side edge of one stator is corresponds to a first side edge of the rectangle, and (d) the outer side edge of the other stator core corresponds to a second side edge of the rectangle.

Note that the above definition of “rectangular cross-sectional profile” allows for there to be gaps between the two top edges of the stator cores and the two bottom edges of the stator cores, as the stator cores are not necessarily in contact with one another and do not necessarily form a single unitary body. More specifically, references to the top edges of the stator cores corresponding to the top edge of the rectangle should not be misunderstood as meaning that the top edges of the stator cores form a continuous line extending fully across the width of the top edge of the hypothetical rectangle, but instead these references should be understood as meaning that that the top edges of the stator cores correspond to two separate portions of the top edge of the rectangle which may be separated by a gap. In other words, the top edges of the stator cores are disposed side-by-side along the top edge of the rectangle with a small gap therebetween near the centerline of the pump. The same is true for the bottom edges.

In addition, the above definition of “rectangular cross-sectional profile” allows for the profile of the stator core to have small deviations from a perfectly rectangular shape, such as having rounded corners, notches/grooves in the edges, chamfers/fillets, etc., so long as the top, bottom, and side edges thereof correspond to the edges of the hypothetical rectangle as defined above. In some examples, an edge of a stator core “correspond to” an edge of the rectangle if the respective edge of the stator core is aligned with and follows (traces) the corresponding edge of the rectangle along at least 70% of the length of the respective edge of the stator core. In some examples, an edge of a stator core “correspond to” an edge of the rectangle if the respective edge of the stator core is within 1 mm of the corresponding edge of the rectangle along at least 70% of the length of the respective edge of the stator core.

In some examples, the cross-sectional profile of the stator core is elongated, meaning the aspect ratio thereof is A:1, wherein A is a number greater than 1. In some examples, the aspect ratio is 1.5:1 or greater. In some examples, the aspect ratio is 2:1 or greater. The aspect ratio refers to the ratio of the width in the horizontal/lateral dimension to the height in the vertical dimension.

During manufacture, the two stator subassemblies 171 and 172 are first formed individually (e.g., by winding the wires around the stator cores and attaching them to the support frames), and then the two stator assemblies 171 and 172 may be disposed on diametrically opposite sides of the impeller chamber portion 133 and are coupled thereto. Next, an inlet subassembly comprising the inlet 131, and an outlet subassembly comprising the outlet 132, are coupled to the impeller chamber portion 133 and the stator assemblies 171 and 172. In this manner, the pump 100 is assembled from multiple subassemblies which are coupled together. Moreover, in some examples, these subassemblies may include different housing portions. These housing portions may combine together to form the housing 110 of the pump once all the subassemblies are coupled together. As a result of this, there may be gaps or seams 112 in the housing where these housing portions meet.

In addition, the pump 100 comprises encapsulant 106, which is injected into the interior of the housing 110 after the various subassemblies have been coupled together. The encapsulant 106 may be injected in liquid form into the housing 110 via holes 181 which are formed in the housing 110 for this purpose. For example, the holes 181 may be formed in a top faces of the pump 100. The encapsulant 106 may flow into the spaces between the stator 120 and the chamber 133 and between the PCA 125 and the chamber 133. The encapsulant 106 then cures, with the resulting solid-form encapsulant filling the space between, and being in mutual contact with, the chamber 133 and the stator 120, and also the chamber 133 and the PCA 125. Thus, a heat transfer path is established between the stator 120 and the liquid coolant in the chamber 133, as well as between the PCA 125 and the liquid coolant. The encapsulant may be thermally conductive, and thus the heat transfer path may efficiently conduct heat. The encapsulant may be, for example, a thermal potting compound, epoxy, or other suitable material which can change phase from liquid form during injection to solid thereafter under normal operating temperatures for the pump 100.

The pump 100 further comprises an encapsulant retaining wrap 102. The encapsulant retaining wrap 102 comprises at least a base, and in some examples also comprises a top cover. The base of the wrap 102 comprises a thin sheet of material that is folded to fit around and cover at least a bottom portion of the housing 110, which includes both the bottom face of the housing and the lower sections of the side walls of the housing 110. In some examples, the base of the wrap 102 is formed from a single continuous (unitary) sheet of material which has been patterned (cut) into an unfolded (flat) shape and then folded along various fold lines to form a folded shape which will fit the housing 110. Thus, the base of the wrap 102 may include a bottom portion which is adhered to a bottom face of the housing 110 and side portions which are integrally connected with the bottom portion and folded ninety degrees relative thereto to (at least partially) cover side walls of the housing 110.

The base of the wrap 102 is configured to cover at least some of the seams 112 between the housing portions, as well as fastener holes or other openings in the housing 110, and to substantially contain the encapsulant in the housing 110. In particular, in some examples, the base of the wrap 102 may cover at least the seams 112 and other holes found in the bottom face of the housing 110, where leakage is most likely to occur. In some examples, seams 112 between perimeter side wall portions of the housing 110 may also be covered by the wrap 102. In some cases, the wrap 102 may allow very small amounts of encapsulant to leak through the seams 112, but the wrap 102 substantially reduces the volume of encapsulant that leaks. In some examples, the wrap 102 keeps the leakage of the encapsulant to less than 5% by volume. In some examples, the wrap 102 keeps the leakage of the encapsulant to less than 1% by volume. Moreover, if there is any leakage, it is contained within the interior of the wrap 102, thereby preventing the unsightly residue from forming on the exterior of the pump 100 where it can be seen. The wrap 102 may be adhered to the housing 110 using adhesives, such as glue, epoxy, or other adhesives.

As noted above, in some examples, the wrap also includes a top cover, in addition to the base described above. The top cover may be a distinct part from the base, in some examples. The top cover is configured to cover a top face of the housing 110. However, in some examples, the top cover is not adhered to the top face prior to injection of the encapsulant, as this may cover the holes 181 through which the injection is done. After injection is complete, the top cover may be adhered to the top face, covering the holes 181 as well as the other seams on the top face of a housing 110.

In some examples, the wrap 102 is formed from thin sheets or foils which each comprise one or more wrap materials. In some examples, at least the base of the wrap 102 is formed from a pliable material which is suitable for being folded into the desired shape after being patterned (e.g., cut). In some examples, the wrap materials may also desirably be durable, as they form an outer surface of the pump and thus will interact (e.g., rub, collide, etc.) with the external environment. For example, the base and/or the cover of the wrap 102 may be made from, or include, any of the materials commonly used for electronics labels/stickers such as vinyl, PVC, polycarbonate, mylar, polyester, polyimide, polypropylene, or the like. In some examples, the wrap materials may also be chosen to facilitate heat transfer through the pump, as described in greater detail below. For instance, in some examples, the base and/or the top cover of the wrap 102 may be made from or include a metal foil or thin metal sheet, such copper, stainless steel, aluminum, etc. In some examples, the wrap 102 may further comprise one or more additional layers that are distinct from the base and/or cover and sit between the housing 110 and the base and/or cover. For example, the wrap 102 may include an intermediate thermally conductive layer, such as an adhesive-backed copper foil or copper sheet, which is disposed between the base of the wrap 102 and the housing 110. In some examples, the wrap 102 may include an additional intermediate thermally conductive layer, such as an adhesive-backed copper foil or copper sheet, which is disposed between the cover of the wrap 102 and the housing 110. These intermediate thermally conductive layers may increase heat dissipation rates by helping to spread the heat generated by the heat generating components throughout the pump 100.

In some examples, the base and/or cover of the wrap 102 may have a laminated structure with multiple layers (which may comprise the same, or different, materials) stacked together and forming a single body. Such a laminated structure may be similar to the above-described arrangements in which an additional layer is disposed between the housing and the base/cover in that in both cases multiple layers are stacked and adhered together, but the laminated structure may be more tightly coupled such that it forms a unified body in which the layers generally cannot be separated without application of destructive techniques.

In addition, the wrap 102 may also serve as a cosmetic cover and/or product label for the pump 100. As a cosmetic cover, the wrap 102 may improve the appearance of the pump 110, for example, by covering up unsightly portions of the housing 110, such as the seams 112, screw holes, tooling marks, etc., and/or by including colors, logos, trade-dress, or other aesthetic features. As a product label, the wrap 102 may carry product identification information, safety information, certification information, user instructions, or other information typically found on product labels. Using the wrap 102 to both retain the encapsulant during manufacture and to serve as the cosmetic cover/product label can reduce material costs and manufacturing steps.

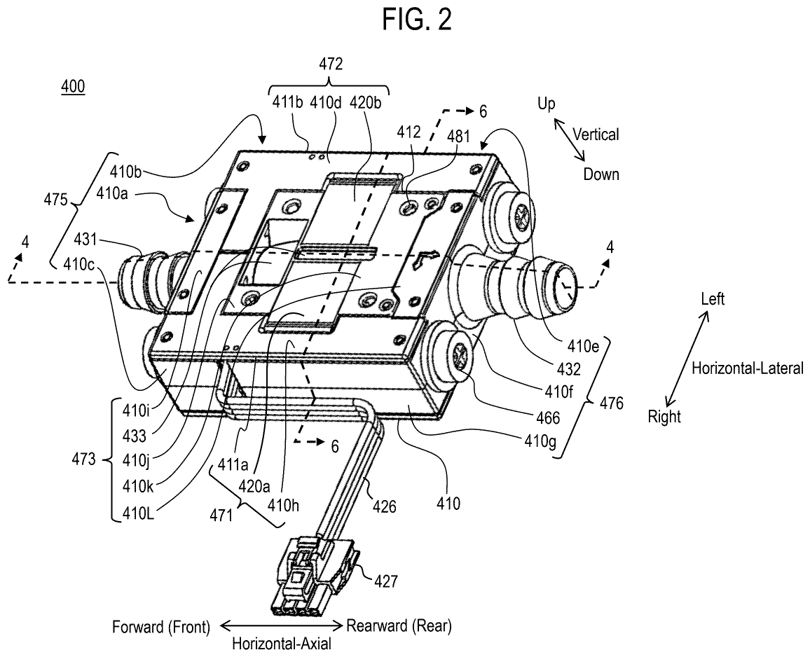

Turning now to FIGS. 2-8, another example pump will be described, in the form of pump 400. The pump 400 is an example implementation of the pump 100 described above. Thus, some components of the pump 400 are similar to (e.g., example implementations or configuration of) corresponding components already described above, and thus the descriptions of the components of the pump 100 above are applicable to the similar components of the pump 400, and duplicative descriptions of certain aspects of the pump 400 may thus be omitted. Corresponding components may be referred to using reference numbers having the same last two digits, such as 110 and 410. It should be understood that the pump 400 is but one possible implementation of the pump 100, and the pump 100 is not limited to the pump 400. Similarly, the individual components of the pump 400 are examples of the corresponding individual components of the pump 100, but the individual components of the pump 100 are not limited to the corresponding components of the pump 400.

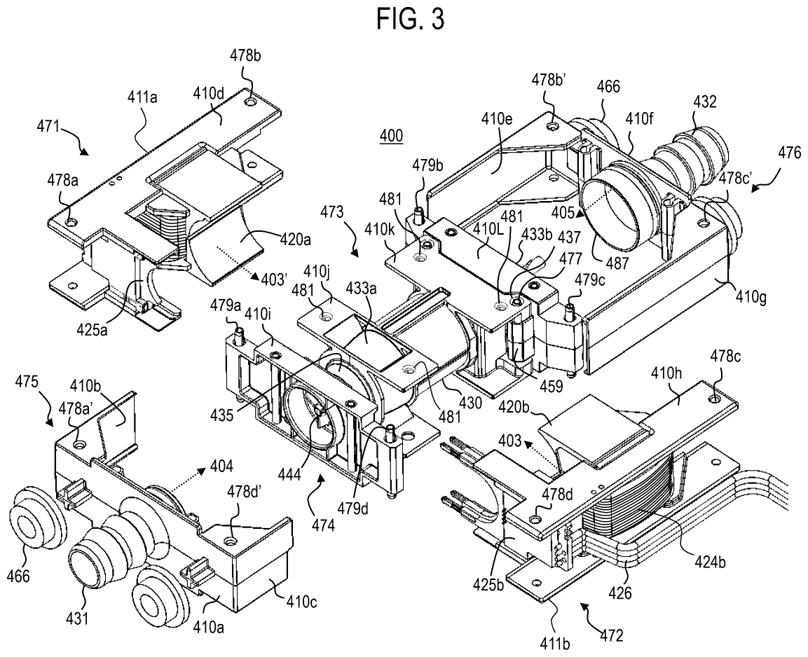

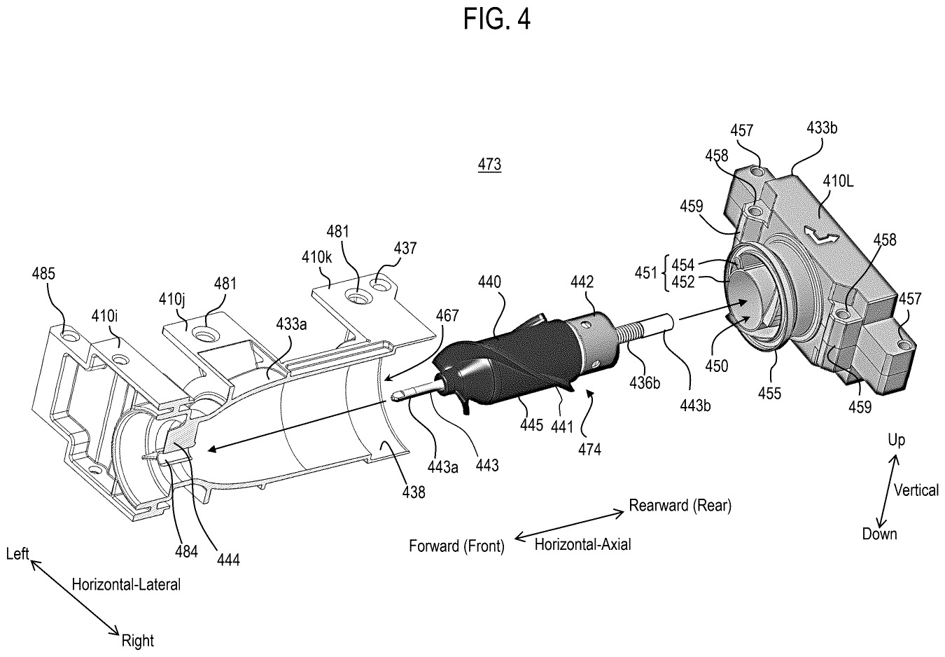

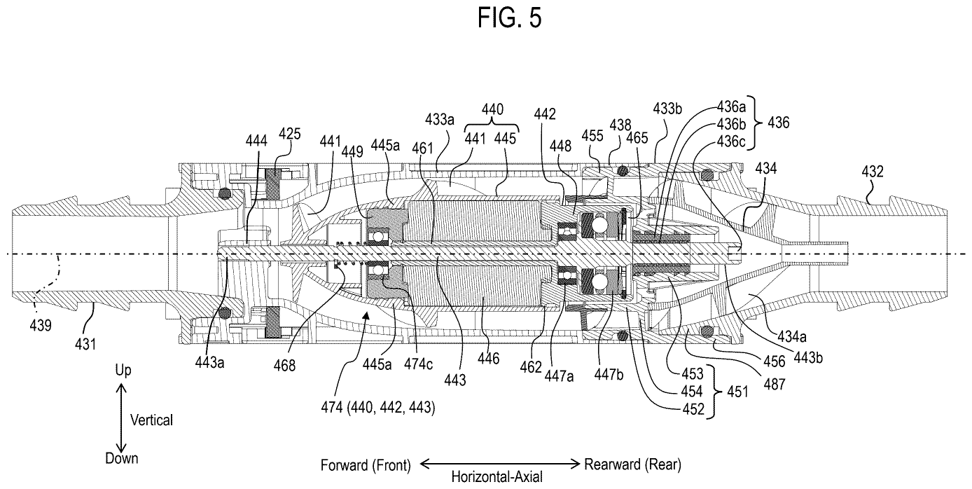

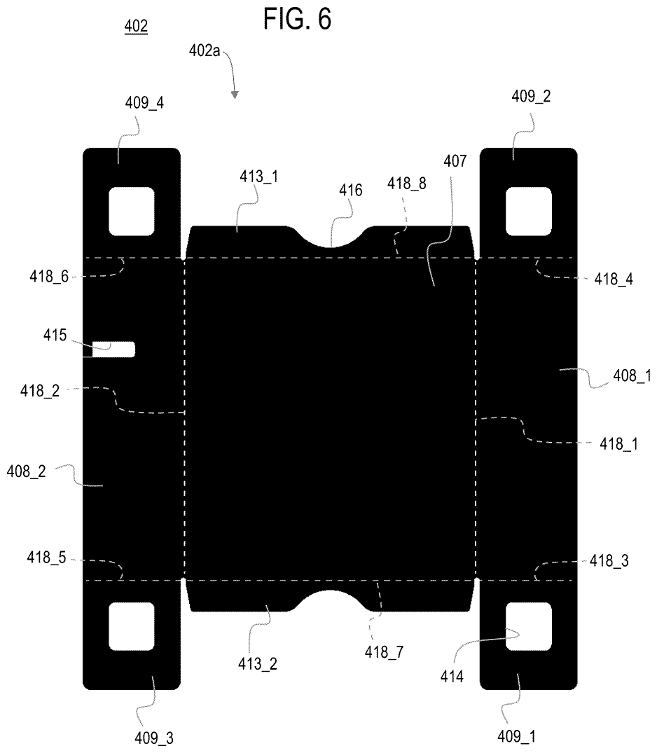

FIG. 2 shows the assembled pump 440, less the wrap, in perspective view. FIG. 3 shows the pump in exploded view. FIG. 4 shows an impeller chamber subassembly 473 of the pump 400 in an exploded and partial cross-sectional view. FIG. 5 shows the pump 400 in a longitudinal cross-sectional view. FIGS. 6-8 illustrate an encapsulant retaining wrap and its application to the pump 400.

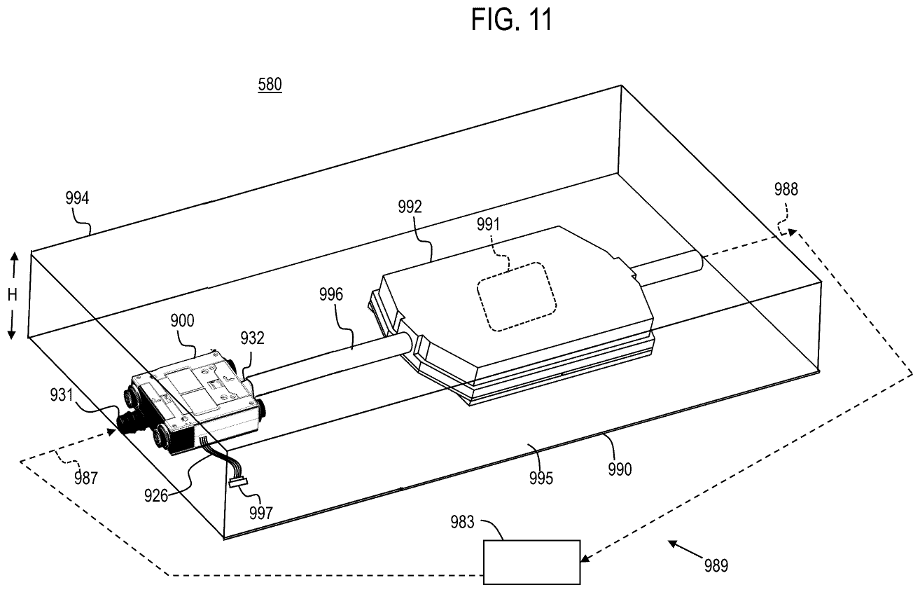

Components of the pump 400 are described below in a hierarchical order intended to facilitate understanding of the structural and functional relationships between the components. However, this order of description is not necessarily the same as the order in which the components appear in the drawings. Thus, FIGS. 2-12 will not be described in strict sequence below. Instead, as aspects of the pump are described, certain figures that are thought to be most helpful to understanding the particular aspect under discussion will be called out, even if that requires moving back and forth between the drawings out of order.

As shown in FIGS. 2 and 3, the pump 400 comprises a number of subassemblies, including a first stator subassembly 471, a second stator subassembly 472, an impeller chamber subassembly 473, an inlet subassembly 475, and an outlet subassembly 476. Each of these subassemblies will be described in greater detail below.

As shown in FIGS. 2 and 3 the first and second stator subassemblies 471 and 472 are positioned on diametrically opposite lateral sides of the impeller chamber. These stator subassemblies 471 and 472 comprise frames 411a and 411b, respectively, which make up part of the housing 410 and which also support other components of the assemblies 471 and 472. The stator subassemblies 471 and 472 also comprise first and second stator portions 420a and 420b held by the frames 411a and 411b, respectively. The stator portions 420a and 420b each comprise a stator core and a wire winding wound around the stator core. In addition, the first and second stator subassemblies 471 and 472 comprise the PCBs 425a and 425b held by the frames 411a and 411b, respectively, which make up a split PCA, such as the split PCA described in the U.S. patent application Ser. No. 17/976,406 entitled “AXIAL PUMP WITH SPLIT PRINTED CIRCUIT BOARD ASSEMBLY (PCA)” and filed on Oct. 28 2022, the entire contents of which is incorporated herein by reference. The stator portions 420a/420b are provided electrical current from the split PCA and, in response, generate the magnetic fields. The stator cores comprises a magnetically susceptible materials which shape and extend the magnetic fields generated by the windings such that they interact with and drive the rotation of the rotor.

As shown in FIGS. 3 and 4, the impeller chamber subassembly 473 comprises an impeller chamber 433 and an impeller/rotor subassembly 474 housed (at least partially) within the impeller chamber 433. The impeller chamber 433 comprises a front portion 433a and a rear portion 433b. The impeller chamber front portion 433a comprises a bore 467 and the rear portion 433b comprises a bore 450. As suggested by the arrows in FIG. 4 when the impeller chamber subassembly 473 is assembled the front portion 433a and rear portion 444b are coupled together with the impeller/rotor subassembly 474 positioned partially inside the bore 467 and partially inside the bore 450. As shown in FIG. 3, the impeller chamber front portion 433a comprises engagement portion 438, which defines a rear opening of the bore 467. As shown in FIG. 5, the impeller chamber rear portion 433b comprises an engagement portion 455 configured to engage with (e.g., be received within) the engagement portion 438 of the front portion 433a to couple the front portion 433a and rear portion 433b together. The engagement portion 455 encircles and defines the bore 450.

As shown in FIG. 4, the impeller/rotor subassembly 474 comprises an impeller 440 coupled to a rotor 442, which is in turn coupled to a shaft 443. The impeller 440 comprises an impeller body 445, blades 441 protruding radially from the impeller body 445 and spiraling axially and circumferentially along and around the outer surface of impeller body 445. The shaft 443 comprises a front end 443a and a rear end 443b.

As shown in FIG. 5, the rotor 442 comprises a bearing tower which includes a bearing tower shaft 461, a front bearing housing 449 attached to a front end of the bearing tower shaft 461, and a rear bearing housing 448 attached to a rear end of the bearing tower shaft 461. The rotor 442 also comprises magnets 446 which are distributed around the bearing tower shaft 461 and fixedly coupled to the bearing tower so as to move together with the bearing tower. The shaft 443 extends through an interior axial boar of the bearing tower shaft 461, as well as through a central bore 469c of the front bearing housing 449 and central openings in the front and rear radial bearings 447a and 447c and rear thrust bearing 447b. The bearing housings 448 and 449 each house bearings 447 that rotatably coupled the rotor 442 to the shaft 443. Specifically, as shown in FIG. 5, the front bearing housing 449 contains front radial bearings 447a that bear radially against the shaft 443, whereas the rear bearing housing 448 contains rear radial bearings 447b that bear radially against the shaft 443 and rear thrust bearings 447c that bear axially against a flange of the shaft 443. The front and rear bearing housings 449 and 448 may also engage with the magnets 446 to help secure the magnets 446 on the shaft 461. A spring clip retainer 465 may be inserted into the rear bearing housing 448 behind the thrust bearing 447b to retain the thrust bearing 447b in the housing 448. A clip 468 may be attached to the shaft 443 forward of the front bearing housing 449, and a spring may be disposed between the clip 468 and the front radial bearing 474c to hold the front radial bearings 447 in the bearing housing 449.

As show in FIG. 5, the rotor 442 (with the shaft 443 coupled thereto) is received within the impeller 440 and the impeller 440 is attached thereto (e.g., via press fitting, adhesives, or other means) to form the impeller/rotor subassembly 447. For example, the front bearing housing 449 may engage with an engagement portion 445a inside a central internal cavity of the impeller body 445 to attach the rotor 442 to the impeller 440. An example of an impeller/rotor subassembly which may be used as the impeller/rotor subassembly 474, as well as an example method of manufacturing such a subassembly, is described in U.S. patent application Ser. No. 18/930,262, the entire contents of which are incorporated herein by reference.

Once the impeller/rotor subassembly 474 is assembled, it may be inserted into the conduit 430 and the shaft 443 may be coupled to the conduit 430. Thus, as the impeller 440 rotates about the shaft 443 it also rotates relative to the conduit 430. As shown in FIGS. 4 and 5, when the impeller chamber subassembly 473 is assembled, the impeller 440 is contained within the impeller chamber 433, with a front end 443 of the shaft 443 thereof coupled to the front portion 433a of the impeller chamber 433 and a rear end 443b of the shaft 443 coupled to the rear portion 433b of the impeller chamber 433. More specifically, a front end 443a of the shaft 443 of the impeller 440 is inserted into a hub 484 in a front support 444, as shown FIG. 5. The front support 444 is coupled to the walls of the impeller chamber 433. Thus, when the front end 443a is engaged by the front support 444, the front support 444 supports the shaft 443 relative to the impeller chamber 433. Similarly, the rear end 443b of the shaft 443 is inserted into and engaged by a rear support 451 of the rear portion 433b of the impeller chamber, as shown in FIG. 5. In particular, an adjustment mechanism 436 is used to couple the shaft 443 to the rear support 451. The adjustment mechanism 436 comprises a nut 436a, a set screw 436b of the shaft 443, and a socket 436c in the end of the shaft 443. The nut 436a is attached to a nut holding portion 453 of the rear support 451 and receives the set screw 436b such that rotation of the shaft 443 relative to nut 436a causes shaft 443 to translate relative to rear support 451. Socket 436c receives a tool to allow rotation of the shaft 443 in this manner.

As shown in FIGS. 4 and 5, the rear support 451 comprises a cylinder 452 encircling the bore 450, a nut holding portion 453 coupled to one end of the cylinder 452, and attachment portions 454 that extend radially from the cylinder 452 to couple the cylinder 452 to the engagement portion 455. Although not visible in the figures, the attachment portions 454 are arranged so as to not block the flow of liquid through the chamber 433, with the liquid flowing through the space between the engagement portion 455 and the cylinder 452 and around the attachment portions 454.

The impeller chamber 433 is also coupled to various support structures and/or comprises various surfaces that form part of the housing 410 and which facilitate joining of the other subassemblies together. For example, as shown in FIG. 4, the rear portion 433b comprises fastener holders 459 with holes 458 to receive fasteners 477. As shown in FIGS. 3 and 4 the front portion 433a comprises holes 437, and when the front portion 433a and rear portion 433b are coupled together the holes 437 align with the holes 458. Thus, as shown in FIG. 3 a fastener 477 is inserted through the holes 437 and 458 to secures the front portion 433a and rear portion 433b in the coupled state. In addition, as shown in FIG. 4, the rear portion 433b also comprises holes 457, which receive fasteners 479b and 479c, as shown in FIG. 3. Similarly, the front portion 433a comprises holes 485, as shown in FIG. 4, to receive fasteners 479a and 479d, as shown in FIG. 3. These fasteners 479a-d are used to couple the various subassemblies together, as will be described below. In some examples, the front portion 433a may also comprise holes 481, which may be used to fill the pump 400 with encapsulant 406 after assembly to make the pump 400 water resistant and also to aid with transfer of heat from pump 400 components into the coolant by removing air gaps. Furthermore, the impeller chamber 433 is coupled to housing portions 410i, 410j, 410k, and 410L.

The inlet subassembly 475 comprises an inlet end wall portion 410a and lateral wall portions 410b and 410c coupled to the inlet end wall portion 410a. The inlet subassembly 475 also comprises the inlet 431 and vibration isolators 466, which are formed in or coupled to the inlet end wall portion 410a. The outlet subassembly 476 comprises an outlet end wall portion 410f and lateral wall portions 410e and 410g coupled to the outlet end wall portion 410f. The outlet subassembly 476 also comprises the outlet 432 and vibration isolators 466, formed in and/or coupled to the outlet end wall portion 410f. In the illustrated example, the inlet 431 and outlet 432 comprise hose barb couplings. In other examples, other types of liquid couplings may be substituted for the hose barb couplings. The pump 400 may be coupled to another device (e.g., a chassis of a computing device that the pump 400 is disposed within) via the vibration isolators 459. The vibration isolators 459 may be rubber, silicon, or another compliant material that helps to absorb vibrations generated by the pump 400 and prevent (or reduce) the transmission of these vibrations to the device in which the pump 400 is disposed. As shown in FIG. 3, the outlet 432 comprises an engagement portion 487. This engagement portion 487 is configured to engage with an engagement portion 456 of the impeller chamber rear portion 433b, as shown in FIG. 5. As shown in FIG. 5, pump 400 also may comprise an outlet guide vane (OGV) 434 which extends into the bore of the engagement portion 487 and the outlet 432 of the outlet subassembly 476. The OGV 434 comprises fins 434a, which guide the flows of liquid as they exit the impeller chamber 433 and enter the outlet 432. This OGV 434 may help to straighten out the flows, removing or reducing some of the circumferential motion of the liquid flows, which is introduced by the rotation of the impeller 440, so that the fluid moves predominantly (or, in some cases, only) axially upon exiting outlet 432.

As shown in FIG. 3, the inlet and outlet subassemblies 475 and 476 may be positioned on opposite axial sides of the impeller chamber subassembly 473. Thus, during assembly of the pump 400 the inlet and outlet subassemblies 475 and 476 may be positioned as shown in FIG. 3 and then moved towards one another (along directions indicated by arrows 404 and 405) until the inlet 431 is fluidically coupled with one side of the impeller chamber 433 and the outlet 432 is fluidically coupled with the other side of the impeller chamber 433. In some examples, this assembly step may occur after the two stator subassemblies 471 and 472 have been assembled onto the impeller chamber subassembly 473. Once the inlet 431, outlet 432, and impeller chamber 433 are coupled together, they form the conduit 430 through which liquid coolant may flow along a central axis 439 thereof.

Once the stator subassemblies 471 and 472 are assembled, they may be assembled together with the other subassemblies of the pump 440 in the following manner. The first and second stator subassemblies 471 and 472 are positioned on opposite lateral sides of the impeller chamber subassembly 473, similarly as shown in the exploded view of FIG. 3. Next, the stator subassemblies 471 and 472 may be moved laterally towards one another and towards the impeller chamber subassembly 473 positioned therebetween (i.e., along the directions 403 and 403′ shown in FIG. 3) until the stator subassemblies 471 and 472 are positioned adjacent to, and partially surrounding, the impeller chamber subassembly 473. In this state, the stator core portions 420a and 420b are positioned adjacent to and radially surround the impeller chamber 433, except for small regions at the top and bottom of the impeller chamber 433, which are not surrounded, as shown in FIG. 2. The frames 411a and 411b of the first and second stator subassemblies 471 and 472 are coupled to the impeller chamber subassembly 473 in this position, for example via engagement of fasteners 479a-d with the holes 478a-d. Moreover, as the stator subassemblies 471 and 472 are brought together around the chamber 433, the PCBs 425a and 425b become electrically coupled together by engagement of electrically connectors thereof which extend over and/or under the chamber 433, as suggested in FIG. 3 and as explained in U.S. patent application Ser. No. 17/976,406. The input assembly 475 and output assembly 476 may then be coupled to the impeller chamber subassembly 473 and the two stator subassemblies 471 and 472, with fasteners 479a-d engaging with holes 478a′-d′.

In some examples, prior to, during, or after the assembly of the stator subassemblies 471 and 472, one of the PCBs 425a/425b may be electrically connected to a power cable 426 which supplies electrical power to the pump 400. This cable 426 is shown coupled to PCB 425b in FIG. 3, but may be coupled to the other PCB 425a in other examples. In FIG. 3, the cable is shown as being permanently coupled to the PCB 425b via soldered connection, but in some examples, the cable may be removably coupled to the PCB 425a or 425b via an electrical connector, such as the electrical connector 425″ illustrated in FIG. 12.

As shown in FIGS. 2 and 3, the pump 400 comprises a housing 410. The housing 410 has a top face, a bottom face, and four side walls extending between and perpendicular to the top and bottom faces. The housing 410 may be made up of multiple distinct portions that are joined together. Specifically, the various subassemblies described above may comprise various structures which together form portions of the housing 410.

The top face of the housing 410 is formed from the top portions 410d, 410h, 410i, 410j, 410k, and 410L. The top portions 410d and 410h are part of the first and second stator subassembly 471 and 472, whereas the top housing portions 410i, 410j, 410k, and 410L are coupled to the conduit 430 and are part of the impeller chamber subassembly 473.

Note that the top face of the housing 410 is not necessarily uniformly flat and does not necessarily fully cover all of the pump 400. For example, a top of the stator portions 420a and 420b may be exposed and approximately coplanar with the top face of the housing 410 (this may allow the height dimension of the pump 400 to be reduced to the absolute minimum possible for a given size of stator 420). Furthermore, portions of the chamber 433 may also be exposed. In some examples, the exposed portions of the stator portions 420a and 420b and chamber 433 may also be considered as being part of the top face of the housing 410. In some examples, epoxy or other filler/sealant may be added to cover these exposed portions, in which case the epoxy or other material may also form part of the top face of the housing 410.

The bottom face of the housing 410 may be similarly constructed as the top face and thus duplicative illustration and description of the bottom face portions is omitted. In particular, in some examples, for each of the top portions 410d, 410h, 410i-410L, there is a corresponding bottom portion which is disposed opposite therefrom and which has a similar configuration as the corresponding top portion. Some minor differences may be found between the top and bottom faces, however—for example, in some implementations, the fill holes 481 may be omitted from the bottom face.

The perimeter side walls of the housing 410 are formed from the inlet end wall portion 410a, lateral wall portions 410b and 410c, outlet end wall portion 410f, and lateral wall portions 410g and 410e. The inlet end wall portion 410a and lateral wall portions 410b and 410c are part of the inlet subassembly 475. The outlet end wall portion 410f and lateral wall portions 410g and 410e are part of the outlet subassembly 475.

Some of the housing portions may include holes 478 (e.g., 478a, 478b, etc.) (only some are labeled) that are arranged to receive a corresponding fastener 479 (e.g., 479a, 479b, etc.) to couple the subassemblies together. For example, in some implementations including the one illustrated in FIG. 3, the impeller chamber subassembly 473 comprises fasteners 479a, 479b, 479c, and 479d. These fasteners may comprise pins (e.g., spring-biased push pins), screws, bolts, pegs, studs, or any other fasteners. The fasteners 479a, 479b, 479c, and 479d may be inserted into corresponding holes 478a, 478a′, 478b, 478b′, 478c, 478c′, 478d, and 478d′ of one more the subassemblies to secure the respective subassemblies together. A single fastener 479 may be inserted through two corresponding holes 478 of two different subassemblies. For example, the fastener labeled 479a in FIG. 3 may be inserted into the two holes labeled 478a and 478a′ which are part of the stator subassembly 471 and the inlet subassembly 475, the fastener labeled 479b may be inserted into the two holes labeled 478b and 478b′ which are part of the stator subassembly 471 and the outlet subassembly 476, the fastener labeled 479c may be inserted into the two holes labeled 478c and 478c′ which are part of the stator subassembly 472 and the outlet subassembly 476, and the fastener labeled 479d may be inserted into the two holes labeled 478d and 478d′ which are part of the stator subassembly 472 and the inlet subassembly 475. Note that only the fasteners 479 and corresponding holes 478 on a top side of the housing 410 are labeled in FIG. 3, but it should be understood that similar holes and fasteners are present on the bottom side of the housing 410 and may be joined in the same fashion.

As a result of the housing 410 being formed from multiple distinct portions, there are gaps or seams 412 in the housing 410 where these housing portions meet. One such seam 412 in the top face of the housing 410 is labeled in FIG. 2, but many more are visible. The bottom face of the housing 410 would have similar seams 412, which are not visible in the figure. The perimeter side walls would also have seams 412, not labeled in FIG. 2.

In addition, the pump 400 comprises encapsulant (not labeled), which is injected into the interior of the housing 410 after the various subassemblies have been coupled together. The encapsulant may be injected in liquid form into the housing 410 via the holes 481 which are formed in the top face of the housing 410 for this purpose. The encapsulant 406 may flow into the spaces between the stator 420 and the chamber 433 and between the PCA 425 and the chamber 433, cure to solid form, and thereby establish a thermal coupling between the chamber 433 and the other parts, as explained above in relation to FIG. 1. The encapsulant may be, for example, a thermal potting compound.

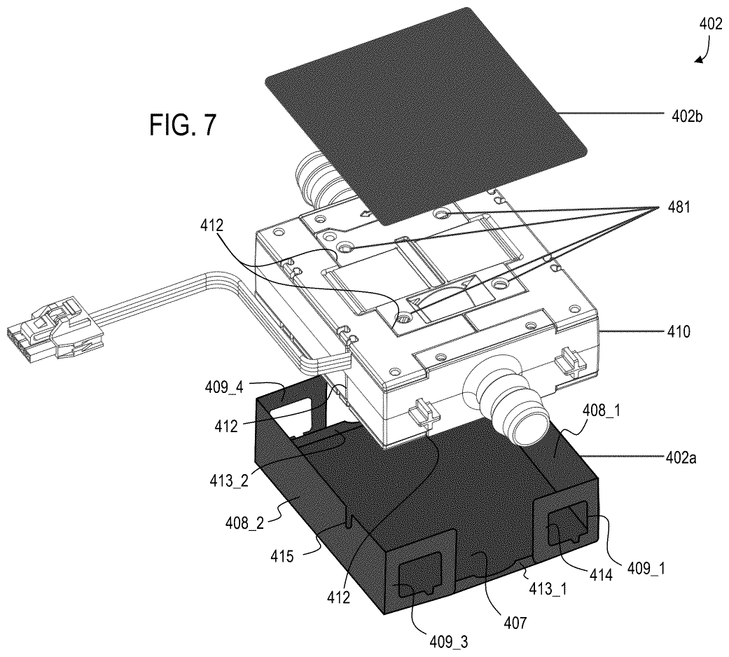

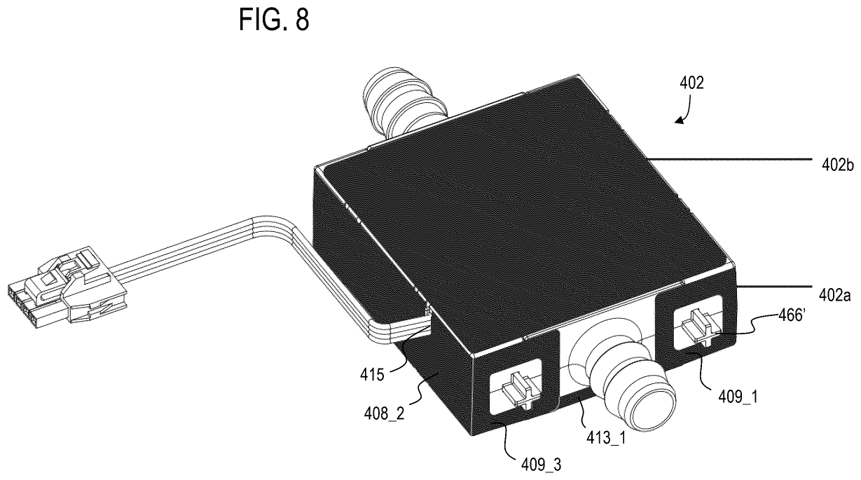

The pump 400 further comprises an encapsulant retaining wrap 402. The encapsulant retaining wrap 402 comprises two parts: a base 402a (shown in FIGS. 6-8) and a top cover 402b (shown in FIGS. 7 and 8). The base 402a of the wrap 402 is formed from a thin sheet of material that is patterned (e.g., cut, molded, etc.) into an unfolded shape shown in FIG. 6. This unfolded shape is configured to be folded into a folded shape that will fit around the bottom portion of the housing 410 of the pump 400. One example of the unfolded shape is shown in FIG. 6, with the dashed lines indicating locations along which folds may be made to form the folded shape shown in FIG. 7. The installation of the base 402a on the pump 400 is shown in FIG. 8.

More specifically, the base 402a comprises a bottom face portion 407 which is arranged to cover the bottom face of the housing 410 when the wrap 402 is installed, as shown in FIGS. 6-8. The bottom face portion 407 has the same shape and similar size as the bottom face of the housing 410.

Furthermore, the base 402a comprises side portions 408_1 and 408_2 coupled to the bottom face portion 407. The side portions 408_1 and 408_2 are folded 90 degrees relative to the bottom face portion 407 along the dashed lines 418_1 and 418_2, respectively. Once folded, the side portions 408_1 and 408_2 are arranged to cover the two lateral side walls of the housing 410 when the wrap 402 is installed, as shown in FIGS. 6-8. (Note that one of these lateral side walls is formed from the lateral wall portions 410b, and 410e, while the other lateral side wall is formed from the lateral wall portions 410c and 410g.) These side portions 408_1 and 408_2 have similar size and shape to the side walls, thus substantially covering most of the surface area of the side walls (e.g., 95% or more, in some examples). When installed, the side portions 408_1 and 408_2 are adhered to the side walls of the housing 110 and the folds along the lines 418_1 and 418_2 are positioned along the bottom lateral edges of the housing 110 where a bottom face of the housing 110 meets lateral side walls of the housing 110. Side portion 408_2 may also have a cutout 415, which is arranged to align with the position where the power cable 426 exits the housing so that the power cable 426 may extend through the cutout 415 when the wrap 402 is installed, as shown in FIGS. 6-8.

The base 402a also comprises four corner tabs 409_1 to 409_4, each of which is attached to one end of one of the side portions 408_1 and 408_2. These corner tabs 409_1 to 409_4 are folded 90 degrees relative to the side portion 408_1 and 408_2 along the lines 418_3 to 418_6, as shown in FIG. 6. Thus, the corner tabs 409_1 to 409_4, when folded, are arranged to cover portions of the inlet end wall portion 410a or portions of the outlet end wall portion 410f of the housing 410, as shown in FIGS. 7 and 8. When installed, the corner tabs 409_1 to 409_4 are adhered to the inlet and outlet end wall portions 410a and 410f, the folds along the lines 418_3 to 418_6 are positioned along the four side corner edges of the housing 110 where lateral side walls meat front or rear side walls of the housing 110. These corner tabs 409_1 to 409_4 may have openings 414 therein which are arranged so as to aligned with the posts 466′ of the vibration isolators 466, allowing the posts 466′ to protrude therethrough.

The base 402a also comprises front and rear ledges 413_1 and 413_2, which are coupled to the bottom face portion 407. The front and rear ledges 413_1 and 413_2 are folded 90 degrees relative to the bottom face portion 407 along lines 418_7 and 418_8 so as to cover the bottom edge of the inlet end wall portion 410a and outlet end wall portion 410f of the housing 410, just below the inlet 431 and the outlet 432, when the wrap 402 is installed, as shown in FIGS. 6-8. The front and rear ledges 413_1 and 413_2 may be folded in front or, or behind, the tabs 409_1 to 409_4.

The top cover 402b is configured to cover the top face of the housing 410, and has a similar size and shape thereto.

In some examples, the base 402a and/or the top cover 402b of the wrap 402 are made from one of the materials commonly used for electronics labels/stickers such as vinyl, PVC, polycarbonate, mylar, polyester, polyimide, polypropylene, or the like. In some examples, the base 402a and/or the top cover 402b of the wrap 402 may be made from a metal foil or thin metal sheet, such copper, stainless steel, aluminum, etc. Or the base 402a and/or the top cover 402b of the wrap 402 may be any other material which is can be easily patterned (e.g., cut) and folded into the desired shape. In some circumstances, the material may desirably be thin, pliable, inexpensive, and durable.

During manufacture of the pump 400, first the various subassemblies of the pump are coupled together, as was described above. Then, the base 402a of the wrap 402 is adhered to the bottom and side portions of the housing 410 of pump 400, as shown in FIG. 8. This results in various seams 412 between the housing portions being covered. In particular, the base 402a of the wrap 402 may cover at least the seams 412 found on the bottom side of the housing 410, where leakage is most likely to occur, as well as seams 412 between perimeter side wall portions of the housing 410. Note that some seams 412 in the top face of the housing 410 are indicated in FIG. 7 as an example, and similar seams 412 (not visible) would be present in the bottom face of the housing 410 and would be covered by the base 402a of the wrap 402.

After the base 402a of the wrap 402 is adhered to the housing 410, the encapsulant may be injected into the housing 410 via the holes 481. Note that the top cover 402b is not coupled to the housing 410 at this stage so that the holes 481 remain accessible for injection. The base 402a of wrap 402 holds the liquid encapsulant 406 within the housing 410, reducing leakage. After injection is complete, the top cover 402b may be adhered to the top face of the housing 410, as shown in FIG. 8, which closes the holes 481 and other seams 412 thereof.

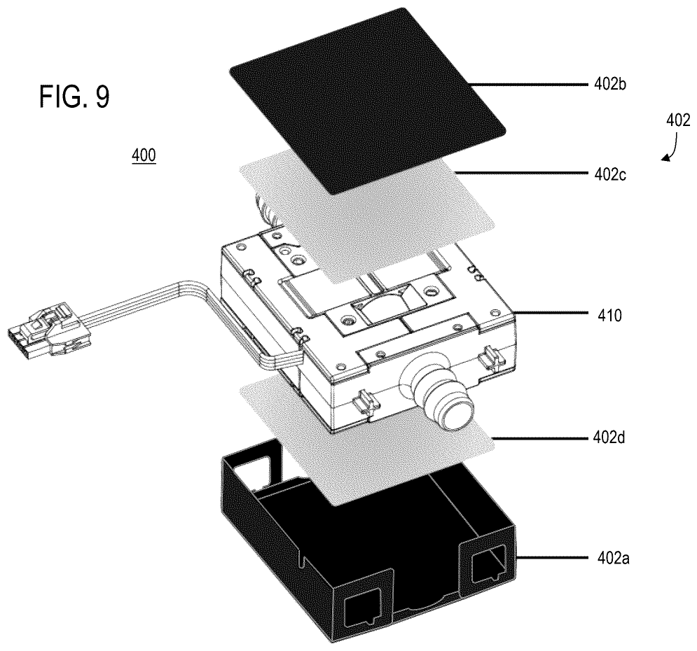

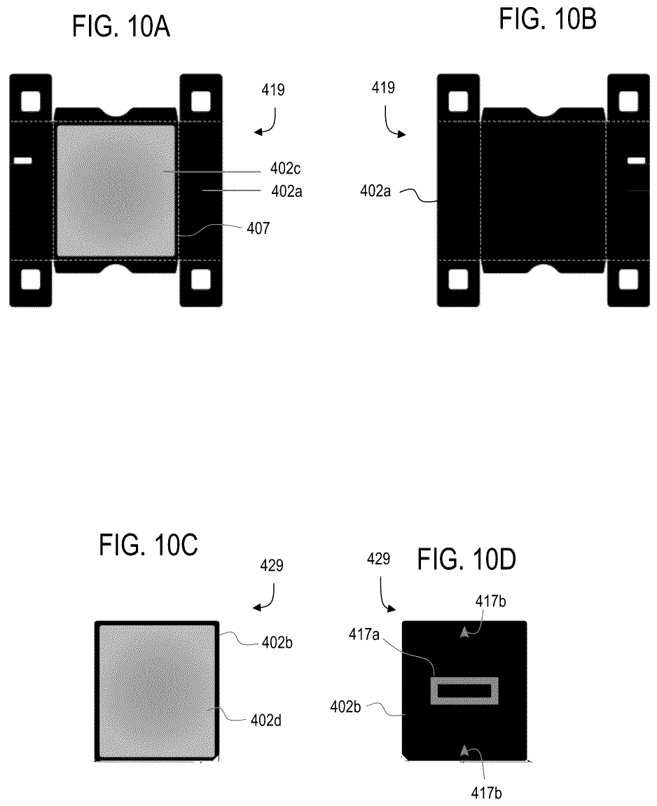

In some examples, the wrap 402 may include additional intermediate thermally conductive layers which are disposed between the housing 410 and the base 402a and cover 402b, respectively. For example, FIGS. 9-10D illustrate an example wrap 402′, which is a variation of the wrap 402 in which intermediate thermally conductive layers 402c and 402d are included. The wrap 402′ may be the same as the wrap 402 described above except for the addition of the layers 402c and 402d in the wrap 402′, and thus identical reference numbers are used in relation to the wraps 402 and 402′ for parts which are the same in both. Descriptions of the wrap 402 herein thus also apply to the wrap 402′, mutatis mutandis, unless indicated otherwise.

The intermediate thermally conductive layers 402c and 402d may each comprise a thin thermally conductive material, such as metal foil or sheet, which is adhered to the housing 410. In some examples, the layers 402c and 402d comprise copper foils. In some examples, the layers 402c and 402d are an adhesive backed metal foil, meaning that an adhesive has been applied to one side of the metal foil. In some examples, such adhesive backed metal foils can be purchased with the adhesive already applied (like a sticker), which can allow the manufacturer of the wrap 402′ to avoid the complication of adding adhesive to the layers 402c and 402d. In other examples, the manufacturer of the wrap 402′ may procure a metal foil without adhesive backing and add adhesive to the layers 402c and 402d and/or to the housing 410.

In examples that include the layers 402c and 402d, the layers 402c and 402d may be adhered directly to the top and bottom sides of the housing 410, respectively, so that they sit between the housing 410 and the base 402a and cover 402b. The layer 402c is adhered to the bottom face of the housing 410 prior to the injection of the thermal encapsulant, and thereafter layer 402c may assist the base 402a in covering seems 412 and other openings in the bottom face housing to retain the encapsulant during and after injection. Subsequently, after encapsulant injection, the layer 402d may be adhered to the top face of the housing 410, covering the injection holes 481. These intermediate thermally conductive layers 402c and 402d may increase heat dissipation rates by helping to spread the heat generated by the heat generating components throughout the pump 400.

In some examples, the layer 402c is coupled to the housing 410 prior to the layer 402c being coupled to the base 402a, and then the base 402a is later installed onto the housing 410, which results in the base 402a covering and becoming coupled to the layer 402c. In other examples, the layer 402c is coupled to the base 402a prior to either being coupled to the housing 410, and then later the combination of the base 402a and layer 402c are installed together as a unit onto the housing 410.

Similarly, in some examples the layer 402d may be coupled to the housing 410 before being coupled to the cover 402b, while in other examples the layer 402d may be coupled first to the cover 402b and then the two may be installed together as a unit onto the housing 410.

The layers 402c and 402d may be generally rectangular or square in shape, having four straight edges joined at right angles. Corners of the layers 402c and 402 may be filleted (rounded) as shown in FIG. 9 or may have any other desired corner shape such as sharp (square), chamfered, etc. Furthermore, in some examples, the layers 402c and 402d may be approximately the same size (in terms of surface area) as, or slightly smaller than, the top and bottom faces of the housing 410. This allows the layers 402c and 402d to substantially cover the top and bottom faces of the housing 410, thereby allowing for improved heat spreading, while also not extending over the sides of the housing 410, which might cause the edge of the layer 402c or 402d to interfere with other parts of the wrap 402′ or to catch on objects in the external environment. Furthermore, the layer 402c may be approximately the same size as, or slightly smaller than, the bottom face portion 407 of the base 402a and the layer 402d may be approximately the same size as, or slightly smaller than, the cover 402b, as shown in FIGS. 10A and 10C, respectively. This may allow for some tolerance in the positioning of the layers 402c and 402d while still ensuring that the base 402a and cover 402b fully cover the layers 402c and 402d.

FIGS. 10A-10D show one example of the wrap 402′ in an unfolded state prior to being assembled on the housing 410. The wrap 402′ includes two assemblies 419 and 429. FIGS. 10A and 10B show two opposite sides of the assembly 419, while FIGS. 10C and 10D show two opposite sides of the assembly 429.

As shown in FIG. 10A, the assembly 419 comprises the base 402a and the layer 402c disposed on the base 402a. FIG. 10A shows the housing-facing side of this assembly 419, i.e., the side which faces the housing 410 when installed thereon. FIG. 10B shows the exterior-facing side of this assembly 419, which is opposite from the housing-facing side, i.e., the side which faces the external environment when installed on the housing 410. In some examples, adhesive may be applied to at least portions of the housing-facing sides of the assembly 419 to facilitate its adherence to the housing 410. In some examples, the layer 402c is also adhered to the base 402a. Moreover, as explained above, in some examples, the assembly 419 may be formed by coupling the layer 402c to the base 402a before the assembly 419 is installed on the housing 410, while in other examples the assembly 419 may be formed simultaneously with the installation thereof on the housing 410 (i.e., the layer 402c is coupled first to the housing 410 and then the base 402a is installed thereon).

As shown in FIG. 10C the assembly 429 comprises the cover 402b and the layer 402d disposed on the cover 402b. FIG. 10C shows the housing-facing side of assembly 429. FIG. 10D shows the exterior-facing side of the cover 429. In some examples, adhesive may be applied to the housing-facing sides of at least portions of the assembly 429 to facilitate its adherence to the housing 410. In some examples, the layer 402d is also adhered to the cover 402b. Moreover, as explained above, in some examples, the assembly 429 may be formed by coupling the layer 402d to the cover 402b before the assembly 429 is installed on the housing 410, while in other examples the assembly 429 may be formed simultaneously with the installation thereof on the housing 410 (i.e., the layer 402d is coupled first to the housing 410 and then the cover 402b is installed thereon).

In addition, the wrap 402 may also serve as a cosmetic cover and/or product label for the pump 400 (the same may be true of the wrap 402′). As a cosmetic cover, the wrap 402 may improve the appearance of the pump 410, for example, by covering up unsightly portions of the housing 410, such as the seams 412, screw holes, tooling marks, etc., and/or by including various visual markings such as colors, logos, trade-dress, or other aesthetic features. As a product label, the wrap 402 may also carry informational visual markings, such as markings related to product identification information, safety information, certification information, use instructions, or other information typically found on product labels. For example, FIG. 10D illustrates one example in which cover 402b includes visual markings 417a in the form of trade dress (e.g., a manufacturer logo) and visual markings 417b in the form of use instructions (e.g., directional arrows to indicate a flow direction through the pump 400). Additional visual markings (not illustrated) may also be included on the cover 402b and/or on the base 402a. In other examples, visual markings different than those shown in FIG. 10D may be included on the cover 402b and/or on the base 402a. Although the visual markings 417 are shown in FIG. 10D in association with an example of the wrap 402′ that includes the layers 402c and 402d, it should be understood that visual markings 417 could be included on other examples of the wrap 402 that lack the layers 402c and 402d. Using the wrap 402 to both retain the encapsulant during manufacture and to serve as the cosmetic cover/product label can reduce material costs and manufacturing steps as compared to providing multiple separate devices to perform these respective functions.

FIG. 9 comprises a schematic diagram illustrating an example system 980 and electronic device 990. The system 980 comprises the electronic device 990 and a liquid cooling loop 989 coupled to the electronic device 990. The system may also comprise additional electronic devices (not illustrated). For example the system 980 may comprise a rack or plurality of racks of electronic devices. The electronic device 990 is illustrated in a state of being installed in the system 980 for convenience of description, but it should be understood that the electronic device 990 may be provided separate from the system 980.

The liquid cooling loop 989 comprises the pump 900 (described below), one or more coolant supply lines 987, one or more coolant return lines 988, and one or more additional cooling loop components 983 such as a heat exchanger, rack-, row-, or datacenter-level coolant distribution unit(s), a chiller, or other cooling components that would be familiar to those of ordinary skill in the art.

The electronic device 990 comprises a PCB 995, such as a baseboard or motherboard of a computing device, and a chassis 994 supporting and housing the PCB 995. The PCB 995 comprises an electrical component 991, such as a processor, power supply unit, memory device, hardware accelerator, or any other electrical component. The electronic device 990 further comprises a cold plate 992 thermally coupled to the electrical component 991.

The electronic device 990 further comprises a pump 900 disposed with in the chassis 994. The pump 900 may be any of the pumps described above, such as the pump 100 and the pump 400. The pump 900 is fluidically coupled with the cold plate 992 via coolant line 996. The pump 900 is electrically connected to the PCB 995 via wires/cable connected to connector 997 of the PCB 995. Thus, the PCB 995 can supply power to and/or communicate with the pump 900. The pump 900 comprises an inlet 931 that may be coupled to the liquid coolant supply line 987 of the liquid cooling loop 989 of the system 980, which supplies liquid coolant to the pump 900. An outlet 932 of the pump 900 is coupled to the coolant line 996. An outlet of the cold plate 992 may be coupled to a liquid coolant return line 988 of the liquid cooling loop, which returns liquid coolant to the remainder of the loop for eventual cooling (e.g., at a heat exchanger). Thus, when the electronic device 990 is installed in the system 980 and fluidically coupled into the liquid cooling loop 989 thereof, liquid coolant from the loop 989 can flow through the pump 900 and cold plate 992. In particular, the pump 900 may be configured to cause (or at least contribute to) the flowing of the liquid coolant through the cold plate 992 to cool the electrical component 991.

It is to be understood that both the general description and the detailed description provide examples that are explanatory in nature and are intended to provide an understanding of the present disclosure without limiting the scope of the present disclosure. Various mechanical, compositional, structural, electronic, and operational changes may be made without departing from the scope of this description and the claims. In some instances, well-known circuits, structures, and techniques have not been shown or described in detail in order not to obscure the examples. Like numbers in two or more figures represent the same or similar elements.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise. Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Elements and their associated aspects that are described in detail with reference to one example may, whenever practical, be included in other examples in which they are not specifically shown or described. For example, if an element is described in detail with reference to one example and is not described with reference to a second example, the element may nevertheless be claimed as included in the second example.

Unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

Further modifications and alternative examples will be apparent to those of ordinary skill in the art in view of the disclosure herein. For example, the devices and methods may include additional components or steps that were omitted from the diagrams and description for clarity of operation. Accordingly, this description is to be construed as illustrative only and is for the purpose of teaching those skilled in the art the general manner of carrying out the present teachings. It is to be understood that the various examples shown and described herein are to be taken as exemplary. Elements and materials, and arrangements of those elements and materials, may be substituted for those illustrated and described herein, parts and processes may be reversed, and certain features of the present teachings may be utilized independently, all as would be apparent to one skilled in the art after having the benefit of the description herein. Changes may be made in the elements described herein without departing from the scope of the present teachings and following claims.

It is to be understood that the particular examples set forth herein are non-limiting, and modifications to structure, dimensions, materials, and methodologies may be made without departing from the scope of the present teachings.

Other examples in accordance with the present disclosure will be apparent to those skilled in the art from consideration of the specification and practice of the invention disclosed herein. It is intended that the specification and examples be considered as exemplary only, with the following claims being entitled to their fullest breadth, including equivalents, under the applicable law.

What is claimed is:

1. An axial pump for delivering liquid coolant to cool an electronic device, comprising:
a conduit defining a flow path from an inlet of the conduit to an outlet of the conduit;
an impeller in the conduit;
a shaft disposed in and coupled to the conduit;
a rotor disposed in a hollow interior of the impeller and rotatably coupled to the shaft, the impeller configured to rotate with the rotor about an axis of rotation extending parallel to the flow path;
a stator configured to drive rotation of the rotor about the shaft and comprising a first stator portion and a second stator portion disposed on diametrically opposite lateral sides of the conduit;
a printed circuit assembly (PCA) configured to supply driving signals to the stator;
a housing formed from multiple distinct housing portions having seams therebetween;
thermal encapsulant inside the housing thermally coupling the stator and the PCA to the conduit; and
an encapsulant retaining wrap adhered to the exterior of the housing and configured to retain the thermal encapsulant in liquid form within the housing by covering at least some of the seams.

2. The axial pump of claim 1,
wherein encapsulant retaining wrap comprises a base and a top cover,
wherein the base is adhered to and at least partially covers a bottom face, side walls, an inlet end wall, and an outlet end wall of the housing,
wherein the top cover is adhered to a top face of the housing.

3. The axial pump of claim 2,
wherein the base is formed from a sheet of wrap material which has been patterned and folded to fit the housing of the pump.

4. The axial pump of claim 3,
wherein the base comprises a bottom face portion, two side portions, four corner tab portions, and front and rear ledge portions all integrally connected together via folds.

5. The axial pump of claim 4,
wherein the bottom face portion is adhered to and covers a bottom face of the housing, the side portions are adhered to and cover side faces of the housing, the corner tab portions are adhered to and cover corner portions of an inlet end wall and an outlet end wall, and the front and rear ledge portions are adhered to and cover bottom edge portions of the inlet end wall and the outlet end wall.

6. The axial pump of claim 5,
wherein the corner tab portions comprise apertures through which stabilizer posts of the pump protrude.

7. The axial pump of claim 5,
wherein one of the side portions comprises an aperture through which a power cord extends.

8. The axial pump of claim 2,
wherein housing comprises a bottom face formed by multiple bottom housing portions, two side walls each formed by multiple side wall portions, an inlet end wall, and an outlet end wall,
wherein the housing comprises bottom seams formed at junctions between the bottom housing portions, at junctions between the bottom face and the side walls and at junctions between the bottom face and the inlet end wall and outlet end wall,
wherein the housing comprises side seams formed at junctions between the side wall portions, and
the encapsulant retaining wrap covers all of the bottom seams and the side seams, except for an opening for a power cord.

9. The axial pump of claim 2,
wherein the encapsulant retaining wrap further comprises one or more thermally conductive intermediate layers disposed between the housing and the base and/or between the housing and the top cover.

10. The axial pump of claim 9,
wherein the one or more thermally conductive intermediate layers each comprise a copper foil.

11. The axial pump of claim 1,
wherein the encapsulant retaining wrap also forms a cosmetic covering and product label for the pump.

12. The axial pump of claim 1,
wherein a top face of the housing of the pump comprises one or more openings configured to facilitate injection of the thermal encapsulant, in liquid state, into the interior of the housing.

13. The axial pump of claim 1,
wherein the first and second stator portions each comprise a stator core portion and
the stator core portions together form a stator core having a rectangular cross-sectional profile.

14. An electronic device, comprising:
a printed circuit board (PCB);
an electrical component coupled to the PCB;
a chassis housing the PCB;
a cold plate thermally coupled to the electrical component; and
the axial pump of claim 1 disposed within the chassis, wherein the conduit of the axial pump is fluidically coupled with the cold plate.

15. The electronic device of claim 14,
wherein the electronic device is a server and the electrical component is a processor.

16. A system, comprising:
a plurality of information processing devices, each comprising a chassis, a printed circuit board disposed in the chassis, an electrical component coupled to the PCB, and a cold plate thermally coupled to the electrical component;
a plurality of instances of the axial pump of claim 1, wherein each of the axial pumps is disposed in the chassis of one of the information processing devices, and the respective conduits of the axial pumps are fluidically coupled with the cold plates of the information processing devices, respectively; and
a liquid cooling loop comprising liquid coolant supply lines configured to supply liquid coolant to the axial pumps, liquid coolant return lines configured to return liquid coolant from the pumps, and a heat exchanger configured to cool the liquid coolant.

17. The system of claim 16,
wherein the axial pumps are individually controllable to individually adjust the flow rate of the liquid coolant through the information processing devices.

18. A method of manufacturing an axial pump, comprising:
connecting a plurality of subassemblies of an axial pump together and forming a housing of the pump from a plurality of distinct housing portions included as parts of the subassemblies, there being seams between the housing portions;
providing a wrap in an unfolded state comprising a wrap material patterned into a predetermined shape;
folding the wrap into a folded shape and adhering the wrap in the folded shape to the exterior of the housing so that the wrap covers at least some of the seams,
injecting a thermal encapsulant in liquid form into the interior of the housing and retaining, by the wrap, the thermal encapsulant in the housing, the thermal encapsulant configured to cure to solid form after injection.

19. The method of claim 18,
wherein the wrap comprises a base and a top cover, the base is adhered to the housing prior to the injection of the thermal encapsulant, and the top cover is adhered to the housing after injection of the thermal encapsulant.

20. The method of claim 19,
wherein the base of the wrap is adhered to and covers a bottom face of the housing, side walls of the housing, and portions of an inlet end wall and an outlet end wall of the housing; and
wherein the top cover is adhered to and covers a top face of the housing.
